(19) United States
(12) Patent Application Publication
(10) Pub. No.: US 2005/0104750 A1
(43) Pub. Date: May 19, 2005

(54) Hexagonal matrix alphanumeric keypad

(76) Inventor: Christopher Tuason, Houston, TX (US)

Correspondence Address: Christopher Tuason, 1447 Pirates Cove, Houston, TX, 77058, US

(21) Appl. No.: 10/990,048

(22) Filed: Nov. 15, 2004

Related U.S. Application Data
(60) Provisional application No. 60/520,033, filed on Nov. 14, 2003.

(51) Int. Cl. H03M 11/00; H03K 17/94

(52) U.S. Cl. 341/22

(57) ABSTRACT

A compact keypad is provided for inputting data into an electronic device. With the addition of a minimum of just four more keys than found on a telephone keypad, direct single-press-per-character data entry is made possible by the use of adjecent combination keypress entries. The keys are sufficiently sized and spaced to enable the direct activation of any of a set of characters comprised of numbers, letters and symbols with a single finger stroke of either one individual key, or an adjacent combination of keys. The present compact keypad conforms to the number-letter association of a standard telephone keypad. Such numerous combinations are made possible because of combinations arising from individual keys being arranged in a close-ordered hexagonal pattern. Seven or more characters can be directly selected with a single press of a single key actuated in combination with any or none of its six adjacent keys. Each individual key is connected to an electro-mechanical contact to produce an electrical impulse corresponding to the individual key being activated. The various combinations are subsequently decoded to generate an input of the single selected character. The number of such direct data entry combinations far exceeds the number of individual keys, so substantially fewer keys are needed than those found on a full set of non-combination enabled keyboards, such as the typical QWERTY keyboard, while still maintaining the same key coding equivalency and a one-to-one key stroke to key code correspondence. Alternate embodiments of the present invention offer two handed touch-typing speed of data entry along with being compatible with current expanded function telephonic keypads.

### FIELD OF THE INVENTION

The present invention is in the field of communications keypads useful for the generation of coded alphanumeric data. More specifically, the present invention relates to an array of manually actuated control elements, each of which is indicative of an individual code value (i.e., character, digit or symbol).

### BACKGROUND OF THE INVENTION

Decreasing the size of portable computers, word processors, cellular telephones, and other handheld electronic devices has been limited by the space needed for a compact yet workable keyboard. As micro-processing hardware capability has improved, additional features, such as text-messaging, arithmetic processing, and wireless Internet access have become possible in ever smaller devices. Miniaturization of electronic circuitry has progressed to a scale below that of the human fingers, with the result that the man-machine interface alone (e.g., screens, keypads, cursor control devices) dictate the size of the device. As a consequence, there is a need for a small-sized man-machine interface which can be used for efficient and accurate data entry into portable and handheld electronic devices. One known way of achieving miniaturization is to use small keys, which, for example, may be arranged in the standard QWERTY keyboard configuration. However, QWERTY keyboard size reductions have heretofore been limited by the ergonomics associated with the size and dexterity of the human fingers.

One space-saving solution for some portable telephones has been to use the regular number buttons to type in the numbers or letters which are commonly associated with those numbered keys on the telephone “touch-tone” keypad. The user presses a number key one or more times to select and display a particular alphanumeric character. This solution permits a user familiar with the traditional “0-9, *, #” telephone keypad to create any number or letter of the alphabet. However, this mode of data entry is cumbersome and inefficient in that many keystrokes are required to produce even the simplest of text messages. To overcome the data-entry and functional limitations inherent in a keypad limited to 12 keys, i.e., 0-9, *, #, most portable telephones now employ at least one quad-directional rocker-button which has multiple function capability built into such button. The user selects the desired functions by pressing down near the appropriate edge. However, most telephones which have this feature typically provide only one such button, and its function usually is limited to scrolling or selecting menu options. Quad-directional buttons have not been adaptable to alphanumeric text entry. The quad-directional rocker-button occupies about the same keypad space as that needed for four regular buttons and adjacent buttons would have to be separated by sufficient distance to prevent the inadvertent simultaneous depressing of two or more. Another space-saving solution has been the independent and combination key keypad, such as that proposed by Levy (U.S. Patent Application Publication No. U.S. 2003/0160712 A1). In such keypads, the electronics are designed to register an individual or multiple-key actuation. These keypads create opportunities for character or function generation much greater than the number of keys themselves. However, the keypad layout geometry of such proposals (i.e. rectangular or triagonal) have limited the functionality of these keypads. The resulting limited number of possible adjacent combination entries that are possible per key have forced the number-letter association of such keypads away from the ubiquitous telephone keypad association. This consequence of the limited geometry is that users are required to learn an unfamiliar layout.

This problem is solved in the present invention by use of a hexagonal matrix, which thereby increases the number of combinations available so that the familiar number-letter association of a standard telephone is preserved.

However, there remains need in the field for an alternative compact keypad that has the features of user familiarity, substantial QWERTY keyboard key coding equivalency, a one-to-one key stroke to key code correspondence, and an appropriately compact layout as required miniaturized electronic devices.

### SUMMARY OF THE INVENTION

The present invention is a space-saving keypad which organizes the “0-9, *, #” keys of a POTS (plain old telephone set) keypad familiar to all telephone users and some additional keys described herein into various arrangements which permit individual keys or combinations of adjacent keys to be depressed by one finger touch. Further embodiments of this invention use novel arrangements of the POTS keypad and other additional keys having hexagonal and circular shapes to form even more compact keypads. Still further embodiments create additional compact keyboards by novel arrangements of the numerals 0-9, letters A-Z, and symbols “*” and “#” into a compact keypad. Still further embodiments add the feature of “asynchronous release” of combination keys to create additional keypad functionality with the same number of keys, such as: shift to caps.

In all of the embodiments, the keys, regardless of their individual shape or layout as a group, are placed in close enough proximity to allow two adjacent keys to be depressed either one-at-a-time, or both simultaneously by a single, one finger key stroke to code for a desired alphanumeric character, symbol, or arithmetic function. For example, one-at-a-time key strokes may create the familiar “0-9, *, #” numbers or symbols in the embodiment based on the familiar “touch-tone” POTS faceplate. Depending on the adjacent key combinations, depressing the keys two-at-a-time with one finger motion (key stroke) creates, for example, the letters A-Z.

Adding keys in addition to the traditional “0-9, *, #” keys creates opportunities for grammatical symbols, arithmetic functions, or other functionality, such as capitalization. The characters which may be created are not limited to ones alphanumeric, symbolic, or arithmetic. The key pad may be associated with hardware and/or software programming to create any desired character, string of characters, or micro-processing function as one skilled in the art may choose. Still further, an electromechanical means designed interface with the present keypad to detect the depressing of one or more keys may be made sensitive enough to detect different levels of applied finger pressure, with distinct tactile feed-back. Such means could be used in combination with the present keypad to distinguish between lower or upper-case characters, or any other desirable feature.

In a preferred embodiment, the present invention provides a hexagonal array of individual keys of the keypad. That is to say, that the individual keys are disposed in a pattern such that any one individual key is part of a grouping of six individual keys symmetrically surrounding one other individual key. The individual keys of the present keypad can be shaped as selectable by one of ordinary skill in the art. For example, preferentially the individual keys are hexagonal or circular, but they could have other shapes as well. Also, the individual keys may be faceted or dimpled to facilitate proper placement or engagement of a user's finger with the desired key or key-pair. The individual keys are disposed in sufficient proximity to permit one-key or an adjacent key-pair to be activated by one finger stroke to cause the corresponding alphanumeric character, grammatical symbol, or arithmetic operation to be displayed or executed. Preferably, the hexagonal array of individual keys are arranged in an inverted “V” pattern consistent with the lengths of the three center digits of the human hand, to facilitate their manipulation. This may be useful in reducing a user's susceptibility to physiological conditions resulting from repetitive hand and finger motions, such as carpel tunnel syndrome.

Activation of a single individual key or a key-pair in combination with an electromechanical contact means corresponding to each individual key of the present keypad is used to produce alphanumeric characters, grammatical symbols, or arithmetic functions. Such electromechanical means will create an electrical impulse associated with each individual key or a key-pair. These electrical impulses are used as the basis for data entry into any number of existing electronic code discrimination circuits as are known in the art to produce an appropriate output coding for the desired alphanumeric character, grammatical symbol, or arithmetic function.

Although the present compact keypad is well suited for adaptation to miniaturized device applications, it should be noted that its compactness resides in the close packing or honey comb disposition of the keypad's individual push-button keys. In addition to miniaturized device applications (such as cell phones) the present key pad is intended for single handed data input applications, where size is not so much the issue, but single handed use and one stroke key coding is. The present keypad can also be utilized to reduce ambiguities that hinder “dictionary matching” types of predictive text applications, such as T9®.

### BRIEF DESCRIPTION OF THE DRAWINGS

FIG. 1 is a top view illustrating the invention with square-shaped keys “0-9, *, #” and additional keys on the left and right for added functionality.

FIG. 2A is a top view illustrating another embodiment of the present invention with hexagonal “0-9, *, #” keys and additional unlabeled keys on the left and right arranged hexagonally.

FIG. 2B is a cross-section view of the hexagonally shaped key labeled “2” from FIG. 2A.

FIG. 3 is a top view illustrating still another embodiment of the present invention with circular “0-9, *, #” keys and additional unlabeled keys on the left and right arranged hexagonally.

FIG. 4 is a top view illustrating a still further embodiment of the present invention with uniform rows of individual keys. All numbers “0-9” and symbols “*” and “#” are located on their own individual keys.

FIG. 5 is a top view illustrating another embodiment of the present invention with non-uniformly rows of individual keys for additional functionality over the embodiment in FIG. 4. All numbers “0-9” and symbols “*” and “#” are located on their own individual keys.

FIG. 6 is a top view illustrating a further embodiment of the present invention with an increased number of individual keys. All letters are located on their own individual keys.

FIG. 7 is an alternate embodiment of the present invention that maintains the a familiar three-by-four rectangular array of number locations that are found on a standard telephone keypad. All letters that are vowels are located on their own individual keys.

FIG. 8 is another embodiment of the present invention that, like the embodiment of FIG. 7, maintains rectangular array of numbers locations that are found on a standard telephone keypad. All letters are located on their own individual keys.

FIG. 9 is similar to FIG. 8, with an alternate orientation of the hexagonal key array. All letters are located on their own individual keys.

### DETAILED DESCRIPTION OF THE INVENTION

Referring now to the drawings, the details of preferred embodiments of the present invention are graphically and schematically illustrated. Like elements in the drawings are represented by like numbers, and any similar elements are represented by like numbers with a different lower case letter suffix.

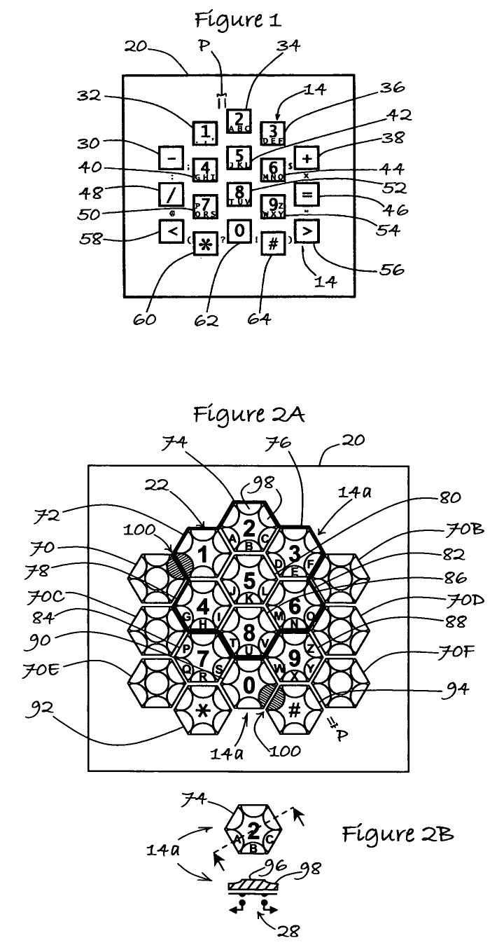

The present invention is a compact keypad for entering data into an electronic device. As shown in FIG. 1, the present compact keypad 20 comprises an array of individual keys 14 coding for various alphanumeric characters and mathematical functions. Each of the individual keys 30-64 are shaped and arranged in a pattern similar to the keys of the familiar plain old telephone set (POTS) keypad. The keys 30 to 64, however, have a span or pitch P separating them, such that one finger applied across the span of any pitch P between two adjacent keys will cause these two keys to be depressed simultaneously.

In a preferred embodiment exemplified in FIG. 1, depressing key 32 alone causes the electromechanical contact means 28 (see FIG. 2B) associated with each individual key 14 to generate an electrical impulse representative of the number “1”. In further fashion, depressing keys 34, 36, 40, 42, 44, 50, 52, 54, or 62, causes electromechanical contact means 28 associated with each key to create an electrical impulse representative of the numbers, 2, 3, 4, 5, 6, 7, 8, 9, or 0, respectively. Still further, an electrical impulse representing the symbols, * or #, may be created by depressing keys 60 or 64, respectively. Depressing keys 30, 38, 48, 46, 58, or 56 causes the electromechanical contact means 28 communicating with each key to electrically represent, respectively, the arithmetic functions, −, +, /, =, <, or >.

Other letters or grammatical symbols may be created by depressing two adjacent individual keys 14 simultaneously, (for example keys 34 and 42) to cause the electromechanical contact means 28 connected to each key to create an electrical impulse to coding for the letter “B”.

In similar fashion, the simultaneous depressing of key-pairs 32 and 34, 34 and 42, 34 and 36, 36 and 42, 36 and 44, 36 and 38, 40 and 48, 40 and 50, 40 and 52, 40 and 42, 42 and 52, 42 and 44, 44 and 52, 44 and 54, 44 and 46, 48 and 50, 50 and 58, 50 and 60, 50 and 62, 50 and 52, 52 and 62, 52 and 54, 54 and 62, 54 and 64, 54 and 56, or 46 and 54 cause the electromechanical contact means 28 connected to each key to create an electrical impulse to coding for the letters, A, B, C, D, E, F, G, H, I, J, K, L, M, N, O, P, Q, R, S, T, U, V, W, X, Y or Z, respectively. Electrical impulses coding for grammatical symbols (e.g., the “@” symbol) may be created simultaneous depressing the appropriate corresponding key-pair. The arithmetic function, “x”, is coded for simultaneous depressing keys 38 and 46.

As illustrated in both FIGS. 1 and 2A, in a preferred embodiment the present compact keypad 20 comprises an array of at least sixteen individual push-button keys 14. In the preferred embodiment, the individual keys 14 of the array are laid out in a hexagon pattern 22, such that any one individual key 14 is part of a grouping of six individual keys 14 symmetrically surrounding one other individual key 14. The arrayed individual keys 14 describe more than one hexagon pattern 22 in the keypad 20.

As further illustrated in FIG. 2A, the individual keys 14a themselves are preferably each hexagon shaped. In the example illustrated, keypad 20 comprises an array of alphanumeric and function keys. Each of the keys 70 to 94, are arranged in the form of a honey-comb to accomplish the compactness of the present keypad 20. The keys 70 to 94 are spaced appropriately apart so that one finger applied at any position across the span P between two adjacent individual keys 14a will cause these two individual keys 14a to be depressed and activated simultaneously as a key-pair.

Another preferred feature of the individual keys 14a of this embodiment, the top surface 96 of the individual keys 14a is adapted to facilitate a user's finger engaging a key-pair across the span P between them. This is accomplished in the embodiment illustrated by forming a dimple 98 on top surface 96 of the individual keys 14a proximate each key edge 74 of its hexagon shape. Forming the individual keys 14a in such fashion causes each individual key 14a to have a profile substantially as illustrated in FIG. 2B. When any two individual keys 14a with like dimpling are placed adjacent to each other a depression 100 (emphasized in the figure with hatching) is formed between the adjacent individual keys 14a of the key-pair. The depression 100 facilitates the positioning of a user's finger when it is desired to activate adjacent individual keys 14a simultaneously. When a plurality of such keys 14a with a formed or dimpled top surface 96 are placed adjacent to each other in the array, the surface of the present keypad 20 has a dimpled appearance overall.

Referring to FIGS. 2A and 2B, depressing the key 72 alone causes its associated electromechanical contact means to generate an electrical impulse coding for the number “1”. In similar fashion, depressing the key 74, 76, 78, 80, 82, 84, 86, 88, or 90, each causes the electromechanical contact means 28 connected to each key to generate an electrical impulse coding for the numbers 2, 3, 4, 5, 6, 7, 8, 9, or 0, respectively. Still further, an electrical impulse coding for the symbols * and #, may be created by depressing the keys 92 and 94, respectively. Depressing keys 70-70F, causes the electromechanical contact means 28 connected to each key to electrically code for any of a number of pre-programmed alphanumeric characters, symbols, or arithmetic or other functions selectable by the ordinary skilled artisan. Other letters or grammatical symbols may be created by depressing adjacent key-pairs. For example, the two impulses generated by simultaneously depressing the keys 74 and 80, can be used to code for the letter “B”.

In similar fashion, the simultaneous depressing of key combinations 72 and 74, 74 and 80, 74 and 76, 76 and 80, 76 and 82, 70B and 76, 70C and 78, 78 and 84, 78 and 86, 78 and 80, 80 and 86, 80 and 82, 82 and 86, 82 and 88, 70D and 82, 70C and 84, 70E and 84, 84 and 92, 84 and 90, 84 and 86, 86 and 90, 86 and 88, 88 and 90, 88 and 94, 70F and 88, or 70D and 80 cause an electromechanical contact means connected to each key to create an additive electrical impulse to represent the letters A, B, C, D, E, F, G, H , I, J, K, L, M, N, O, P, Q, R, S, T, U, V, W, X, Y, or Z, respectively. In a like manner, other grammatical symbols or other functions may be coded for using the keys 70A-F by pre-programing the electronic device with which the keypad 20 communicates to accomplish the desired results when depressed either individually or in combination with other adjacent individual keys 14a.

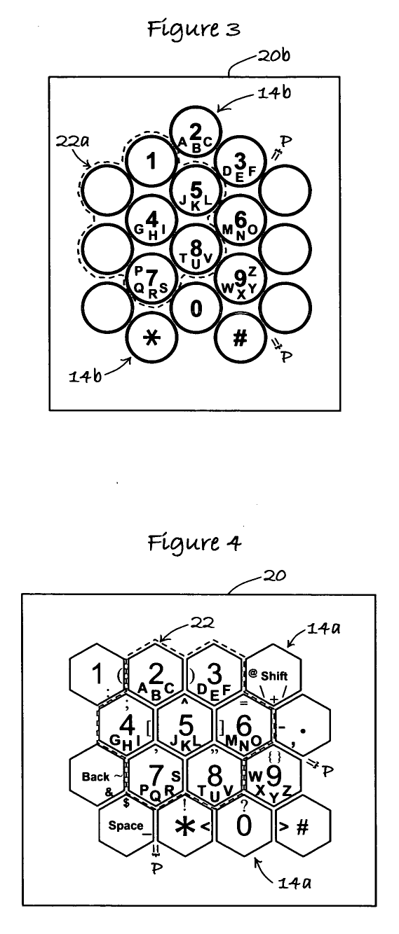

FIG. 3 illustrates an alternative preferred embodiment of the present keypad 20, wherein the individual keys 14b are circular and arranged in a close-ordered repeating hexagon pattern 22a. The operation of the individual keys 14b of the illustrated keypad 20 of FIG. 3 is similar to that of the keypads 20 of FIGS. 1 and 2A.

FIG. 4 depicts another embodiment of the present compact keypad 20, in which the key array consists of sixteen hexagonally shaped individual keys 14a arranged in hexagonal patterns 22. In comparison with FIG. 2A, the key array of FIG. 4 consists of in line rows of individual keys 14a, whereas in FIG. 2A the key array consists of in line columns. Depressing the keys 1-9, *, #, or 0 individually codes respectively for these characters. Additional individual keys represent the character “.” and the functions: “shift,” “back,” and “space.” Two-key or three-key combinations are used to create additional characters, symbols, or functions. For example, pressing simultaneously the key-pair combinations of keys 2 and 4, 2 and 5, 3 and 5, or 3 and 6 produce the letters A, C, D and F, respectively. Further, simultaneous depressing of the keys 2, 4 and 5 produce the letter B. “Multi-Tap” capabilities can be easily integrated into the present keypad 20 in any of the single finger stroke modes: with an individual key 14 or with a two or three keys simultaneously. As an example of the flexibility of the present keypad 20, FIG. 4 illustrates in the insert box that it is possible to adapt the keypad 20 to utilize more than one finger stroke, but that such adaptation is not necessary to accomplish a substantially full QWERTY character set with only a few more individual keys 14.

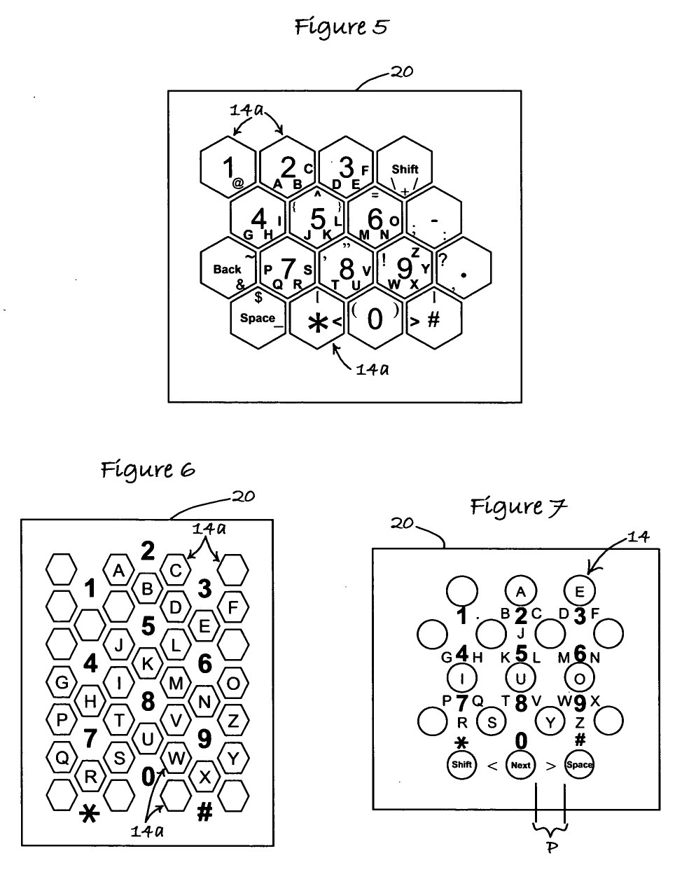

FIG. 5 depicts an embodiment of the present keypad 20 similar to that of FIG. 4, but with a different character set and a different number of individual keys 14a (i.e., seventeen versus sixteen). Characters, symbols and arithmetic functions are coded for in a similar manner as that for FIG. 4, by depressing an individual key 14a, a key-pair or a three-key combination. FIG. 5 illustrates that the present compact keypad 20 may be practiced with a variety of character and function sets and different shaped individual keys 14 (e.g., hexagonal, circular, etc.) as selectable by one of ordinary skill in the art.

FIG. 6 illustrates how the present compact keypad 20 can be practiced with individual keys 14a focused as letters instead of numbers. In this key array, there are individual keys 14a for each of the letters A to Z along with individual keys for other symbols and functions. To generate the numeral 0-9 and the symbols * and # in this embodiment, the several individual keys 14a adjacent to the key space 15 labeled for that character are simultaneously depressed. For example, to generate the number “8” a combination of the surrounding individual keys 14a (i.e., keys I, K, M, T, U and V) are depressed. Note that there is not an individual key 14a for the character in the key space 15, and that the key space is the center of a hexagon pattern. Generating the characters associated with an actual individual key 14a is accomplished in the usual fashion by pressing the specific individual key 14a, or simultaneously pressing the appropriate combination of adjacent keys. For example, the letter K can be coded for by simultaneously depressing the keys I, J, K, L, and M together, or by pressing the key K individually. The letter P can be coded for by simultaneously depressing the keys G, H, P and Q together, or by pressing the key P individually. This feature of the present compact keypad 20 is useful when it is desired to have limited set of individual keys in a physically small array.

For more functionality, all of the keypads 20 of the present invention exemplified in the figures may be combined with “asynchronous release” type electromechanical contacts (not shown) to accomplish coding for still more characters and/or functions, such as shift to caps. “Asynchronous release” refers to rolling the finger off of depressed combination keys upward or downward or to either side, with each variation having the potential for a different function, such as a “roll up” coding for a shift up to caps when the default is lower case, or a “roll down” decoding to a shift down to lower case when the default has been set to upper case (cap lock). More keypad functionality may be achieved by “mash-shift” through the asynchronous release of a combination of keys as can be accomplished by rolling the finger or thumb onto that key or combination of keys.

The key shapes representing the numbers 0-9, letters A-Z, grammatical symbols, and arithmetic functions shown in the figures and described herein are merely representative of those which may be used for text messaging and data processing by one-key, two-key, or three-key combinations. Any number of different key-shape combinations or characters, symbols, or arithmetic functions represented by the keys or key combinations may be created by the depressing of one-key, two-key, or three-key combinations depending on the use and design of any particular keypad.

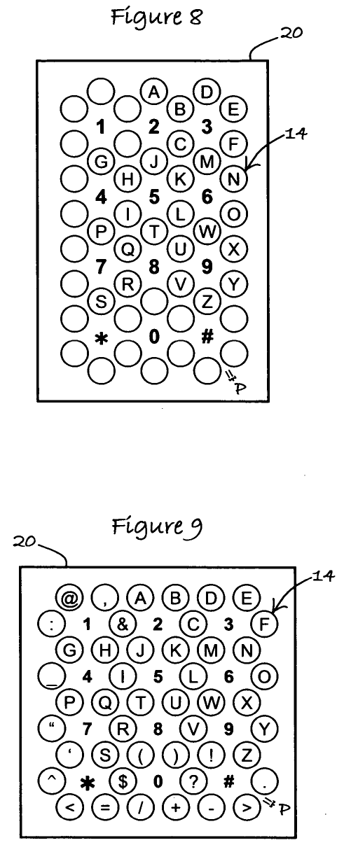

FIGS. 7, 8 and 9 offer alternative embodiments that shift the ergonomic emphasis toward alphabetic text entry over numerical character entry. FIG. 7 is an alternate embodiment of the present invention that maintains the a familiar three-by-four rectangular array of number locations that are found on a standard telephone keypad. All letters that are vowels are located on their own individual keys. FIG. 8 is another embodiment of the present invention that, like the embodiment of FIG. 7, maintains rectangular array of numbers locations that are found on a standard telephone keypad. All letters are located on their own individual keys. FIG. 9 is similar to FIG. 8, with an alternate orientation of the hexagonal key array. All letters are located on their own individual keys.

While the above description contains many specifics, these should not be construed as limitations on the scope of the present invention, but rather as exemplifications of one or another preferred embodiment thereof. Many other variations are possible, which would be obvious to one skilled in the art. Accordingly, the scope of the invention should be determined by the scope of the appended claims and their equivalents, and not just by the embodiments.

1. A compact keypad for entering data into an electronic device, the keypad comprising:
a key array of at least seven individual push-button keys, and at least seven of the individual keys being disposed in a hexagonal pattern wherein any one individual key is part of a grouping consisting of six individual keys adjacent to and surrounding one central individual key;
each individual key having a top surface adapted to be engaged and depressed by a user's finger, and being further adapted to be in electro-mechanical communication with an electrical contact, which contact is activated upon the individual key being depressed; and
a pitch between adjacent pairs of individual keys at their top surfaces, the pitch being disposed to allow the individual keys of an adjacent key-pair to be selectably engaged and depressed simultaneously by the user's finger.

2. The compact keypad of claim 1, wherein the key array comprises sixteen to thirty-seven individual push-button keys.

3. The compact keypad of claim 1, wherein the central individual key disposed in the hexagonal pattern, in combination with an adjacent individual key can code for up to seven separate characters of a character set with a single finger stroke.

4. The compact keypad of claim 1, wherein the key array comprises a plurality of hexagonal patterns of individual keys .

5. The compact keypad of claim 1, wherein the individual push-button keys have a top surface that is substantially circular shaped.

6. The compact keypad of claim 1, wherein the individual push-button keys have a top surface that is substantially hexagonal shaped.

7. The compact keypad of claim 1, wherein the individual push-button keys have a top surface adaptation comprising six partial circle dimples symmetrically disposed at an outer edge of the top surface of each individual key.

8. The compact keypad of claim 1, wherein the pitch between adjacent pairs of individual keys at their top surfaces ranges from about 0.01 inch to 0.25 inch.

9. The compact keypad of claim 1, wherein the grouping of the six individual keys adjacent to and surrounding one central individual key are symmetrically disposed around the central individual key.

10. A compact keypad of claim 1, wherein the key array and the individual keys are miniaturized so that one finger stroke can encompass all of the individual keys in the hexagonal pattern, and any one individual key is part of a group consisting of six individual keys adjacent to and surrounding a central key space.
